(19) United States
(12) Patent Application Publication
(10) Pub. No.: US 2004/0196081 A1
(43) Pub. Date: Oct. 7, 2004

(54) Minimization of clock skew and clock phase delay in integrated circuits

(76) Inventors: Sandeep Srinivasan, Palo Alto, CA (US); Paul Berevoescu, Mountain View, CA (US)

Correspondence Address: Anthony T. Cascio, Esq., Suite 314, 423 Broadway Ave., Millbrae, CA, 94030, US

(21) Appl. No.: 10/405,926

(22) Filed: Apr. 1, 2003

(51) Int. Cl. H03K 5/01

(52) U.S. Cl. 327/165

(57) ABSTRACT

A hierarchal block for an integrated circuit includes a plurality of sequential registers, a plurality of clock cluster buffers, and a plurality of clock pins. The sequential registers are grouped into a plurality of clusters. Each of the clock cluster buffers is associated with a respective one of the clusters such that a clock net connection can be made to a clock gate input of each of the registers in the respective one of the clusters. Each of the clock pins is associated with a respective one of said clock cluster buffers such that a clock net connection can be made between each clock pin and the respective one of the clock cluster buffers.

### BACKGROUND OF THE INVENTION

The present invention relates generally to clock nets in integrated circuits and more particularly to an apparatus and method in which the clock net has multiple clock entry points into a hierarchal block to minimize clock skew and clock phase delay in synchronous circuits.

Synchronous circuits are used in the design of substantially all commercially available complex integrated circuits, and other such circuits otherwise known in the art. In synchronous circuits, the clock signal, delivered through a clock net of such circuits, must be applied to the synchronizing elements within a specified time period. This time period is referred to as the clock phase delay.

The difference between the largest and the smallest clock phase delay on the integrated circuit is known as clock skew. For the integrated circuit to operate at a specified frequency, F, the clock phase delay to all of the synchronizing elements must further be substantially equal. More particularly, the maximum operating frequency, F, of a synchronous integrated circuit is the inverse of a minimum clock period, T_{cycle}, which may be stated as follows:

F=1/T_{cycle}.

The minimum clock period, T_{cycle}, is dependent upon certain parameters such that

T_{cycle}>=t_{d}+tᵢₙₜ+t_{skew}+tₛₑₜᵤₚ+tₚᵣₒₚ,

wherein

t_{d}=maximum/minimum delay thru any combinational logic;

tᵢₙₜ=interconnect delay on the logic path;

t_{skew}=the clock skew on the integrated circuit;

tₛₑₜᵤₚ=setup time of the synchronizing elements; and

tₚᵣₒₚ=propagation delay through the synchronizing elements.

The above parameters and their respective significance upon the operating frequency of the integrated circuit may best be explained in the context of an exemplary simple sequential circuit 10, as best seen in FIG. 1A (Prior Art), which may include a first register 12, a second register 14 and combinational logic 16 therebetween. Each of the first register 12 and the second register 14 have a data input D, a data output Q and a clock input C. The combinational logic 16 is disposed between the output Q of the first register 12 and the input D of the second register 14. A clock signal, CLK, is applied to the clock input, C, of each of the first registers 12 and the second register 14. In the exemplary synchronous circuit 10, the first register 12 and the second register 14 may be further referred to as a launching register and a receiving register, respectively.

In the exemplary sequential circuit 10, the delay, td, through the combinational logic 16 and the delay, tₚᵣₒₚ, through the second register 14 are shown. The interconnect delay, tint, would occur on the logic path between elements.

Referring now to FIG. 2 (Prior Art), there is shown an exemplary timing diagram of the clock signal CLK at the clock input C of the receiving register 14 and a data signal DT received at the data input D of the receiving register 14. The setup time, tₛₑₜᵤₚ, of the receiving register 14 is defined as the amount of time required for the data signal DT to arrive at data input D of the receiving register 14 prior to the clock signal CLK arriving at the receiving register 14. The requirement for the setup time, tₛₑₜᵤₚ, puts a constraint on the maximum logic delay from the output Q of the launching register 12 through the combinational logic 16 to the input D of the receiving register R2.

More particularly, for the circuit 10 to operate at a specified frequency, the following relationship needs to be satisfied:

T_{cycle}>=t_{d(max)}+tᵢₙₜ+t_{skew}+tₛₑₜᵤₚ+tₚᵣₒₚ

or

t_{skew}<=T_{cycle}−(t_{d(max)}+tᵢₙₜ+tₛₑₜᵤₚ+tₚᵣₒₚ).

Furthermore, the data signal DT needs to be held stable for a requisite period of time, known as the hold time, t_{hold}, after the clock signal CLK changes state. If the data is not held stable for the requisite hold time, a race condition results in which the circuit will not operate even if the frequency is lowered. For a sequential circuit to operate correctly, the following relationship needs to be satisfied”

T_{cycle}>=t_{d(min)}+tᵢₙₜ+t_{skew}+t_{hold}+tₚᵣₒₚ

Registers are considered logically adjacent when they are connected directly to each other through combinational logic, such as the first register 12 connected to the second register 14 through the combinational logic 16. The clock skew, t_{skew}, between logically adjacent registers, which can be defined as the maximum time difference in the clock signal CLK arriving at the clock-pin C of each of the first register 12 and the second register 14, determines the maximum frequency and reliability of operation of the integrated circuit.

For example, as best seen in FIG. 3 (Prior Art), a representation of clock skew is shown wherein the clock signal CLK arrives at the clock input C of the first register 12 at a time t_{R1} and at the clock input C of the second register 14 at a time t_{R2}. The clock skew is thus the difference between t_{R1} and t_{R2}. If t_{R1} lags t_{R2}, as seen in FIG. 3 (Prior Art), the skew is positive. Conversely, if t_{R1} leads t_{R2}, the skew is negative.

As is well known, the performance of a sequential circuit can degrade if there is positive skew between two adjacent registers. For positive skew between adjacent registers, i.e., when tᵣ₁>tᵣ₂, the maximum frequency, as determined by the minimum clock period can be determined from the following relationship.

t_{skew}<=T_{cycle}−(t_{d(max)}+tᵢₙₜ+tₛₑₜᵤₚ+tₚᵣₒₚ) for tᵣ₁>tᵣ₂

Under the positive skew condition shown in FIG. 3 (Prior Art), the receiving register 14 will have its setup time requirement violated, since the data launched from the first register 12 will be late due to clock arriving late at the first register 12 in the previous clock cycle.

The constraint on the minimum path delay t_{d(min)} between two registers arises when there is negative skew between logically adjacent registers. In such case, there can be a potential race condition. For example, the data at the input D of the receiving register 14 may not be stable when the clock CLK arrives at this register. This condition can be described by the following relationship wherein:

t_{skew}<=t_{d(min)}+tᵢₙₜ+t_{hold} for tᵣ₂>tᵣ₁

For high frequency synchronous designs to operate reliably, it is therefore highly desirable to minimize clock skew. However, clock skew can vary with process, temperature, voltage and design layout. Furthermore, clock networks on an IC typically span the largest area of the chip, making the clock structures susceptible to process variation, leading to unreliable operation of the IC.

Although many prior art solutions that address that minimization of clock skew and clock phase delay are known for ‘flat’ designs, i.e. designs without hierarchy, a majority of the complex designs today are being done with hierarchical approaches; also know as ‘block based designs’. However, introduction of hierarchy introduces a limitation and disadvantage of loss of information and granularity.

In the hierarchal design, clock skew and phase delay information is abstracted for each individual block in the hierarchy. Clock skew and phase delay is then optimized for each block and the abstracted information is then stored in association with the clock pin for the block abstraction. All of the blocks are then coupled together with the clock phase delay information for each block that has been stored on the clock-pin of the block abstraction. A limitation and disadvantage of the data abstraction is that the circuit performance is limited by the worst skew and phase delay among all blocks. This disadvantage and limitation arises from the fact that each block has only a single entry point, or pin, for the clock into each block.

For example, as best seen in FIG. 4 (Prior Art), an exemplary block based design of an integrated circuit 18 includes a plurality of blocks, such as blocks 20₁₋₃ wherein each of the blocks 20₁₋₃ is of a different physical size. Each of the blocks 20₁₋₃ has a single clock entry point or pin 22₁₋₃ through which the clock signal is fed into each respective one of the blocks 20₁₋₃.

A clock tree 24₁₋₃ is built in each respective one of the blocks 20₁₋₃. Each tree 24₁₋₃ consists of buffers 26 wherein the buffers 26 are provided to minimize the skew and phase delay within each of the blocks 20₁₋₃. The phase delay and skew of each of the blocks 20₁₋₃ is represented on each respective one of the clock pins 22₁₋₃. The blocks 20₁₋₃ are then assembled to make the top level of the integrated circuit 18. At the top level of the integrated circuit 18, a top level clock tree 28 is constructed to minimize the clock skew between the blocks 20₁₋₃.

Typically, the blocks 20₁₋₃ are constructed independently of each other and then assembled into the top level of the design of the integrated circuit 18. Also, as best seen in FIG. 4 (Prior Art), each of these blocks 20₁₋₃ have a different physical dimension from each other. The differing physical dimensions are typical in integrated circuit design methodologies, and it is known that substantially 99% of integrated circuits designed with the block-based methodology have non-uniform block sizes.

A disadvantage and limitation of the block based design as described above is that, due to the different block sizes, the phase delays for each one of the blocks 20₁₋₃ will vary by a large degree. To match these different phase delays, the top-level clock tree 28 needs to be balanced to equalize the longest to the shortest block phase delays for the integrated circuit 18 to work correctly.

Table I, below, sets forth representative phase delays for each of the blocks 20₁₋₃ in the exemplary integrated circuit 18. As best seen in Table 1, in-order to achieve zero skew at the top level of the integrated circuit 18, block 20₂ B needs to be padded with 5.0 ns of delay, and block 203 needs to be padded with 4.5 ns of delay.

TABLE I

| Block | No. Instances | Phase Delay |
|---|---|---|
| 20₁ | 100,000 | 6.5 ns |
| 20₂ | 20,000 | 1.5 ns |
| 20₃ | 30,000 | 2.0 ns |

A disadvantage and limitation of delay padding is that a large number of buffers usually need to be added to the integrated circuit. For example, in smaller process geometries, such buffers typically have a delay through them in the order of 150 ps or less. To introduce 4.5 ns of delay would require thirty such buffers that have a delay of 150 ps each.

Extrapolating from the simple exemplary integrated circuit 18 to higher levels of integration of a complex integrated circuit, it can be appreciated that the block sizes can vary significantly. The divergent block sizes thus result in highly imbalanced clock phase delays through all of blocks. In order to achieve good skew for these imbalanced phase delays, a large number of buffers must be added to the complex integrated circuit to match the block phase delays.

### SUMMARY OF THE INVENTION

It is a primary object of the present invention to overcome one or more disadvantages and limitations of the prior art hereinabove enumerated.

It is a further object of the present invention to minimize clock skew and phase delay in complex integrated circuits.

It is yet another object of the present invention to provide multiple top level clock pins having substantially similar clock skew and phase delay abstractions to hierarchal blocks.

According to the present invention, a hierarchal block for an integrated circuit includes a plurality of sequential registers, a plurality of clock cluster buffers, and a plurality of clock pins. The sequential registers are grouped into a plurality of clusters. Each of the clock cluster buffers is associated with a respective one of the clusters such that a clock net connection can be made to a clock gate input of each of the registers in the respective one of the clusters. Each of the clock pins is associated with a respective one of said clock cluster buffers such that a clock net connection can be made between each clock pin and the respective one of the clock cluster buffers.

A feature of the present invention is that each clock pin provides a separate entry point into the hierarchal block. In a further embodiment of the present invention, each clock pin, when abstracted, can be advantageously provided with a uniformity at the top level of the block based design such that the clock skew and phase delay at each pin is substantially similar to the clock skew and phase delay at each other pin.

Other objects, advantages and features of the present invention will become readily apparent to those skilled in the art from a study of the following Description of the Exemplary Preferred Embodiments when read in conjunction with the attached Drawing and appended claims.

### BRIEF DESCRIPTION OF THE DRAWING

FIG. 1 is an exemplary prior art sequential circuit;

FIG. 2 is a timing diagram of illustrative of hold time and setup time in the circuit of FIG. 1;

FIG. 3 is a timing diagram illustrative of clock skew in the circuit of FIG. 1;

FIG. 4 is an exemplary prior art block based design of an integrated circuit;

FIG. 5 is an exemplary block based design of an integrated circuit in accordance with the principles of the present invention;

FIG. 6 is a plot of clock cluster phase delay distribution;

FIG. 7 is plot of skew distribution within clusters;

FIG. 8 is a plot of normalized delay plotted as a function of buffer area for various loads;

FIG. 9 is an exemplary placement of clock pins within each of the clusters of FIG. 5;

FIG. 10 is a flowchart illustrative of a method of the present invention;

FIG. 11 is a flowchart of the estimating step of FIG. 10;

FIG. 12 is a flowchart of the block level implementing step of FIG. 10;

FIG. 13 is a Delaunay triangulation graph useful in the forming step of FIG. 12; and

FIG. 14 is a flowchart of the top level implementing step of FIG. 10.

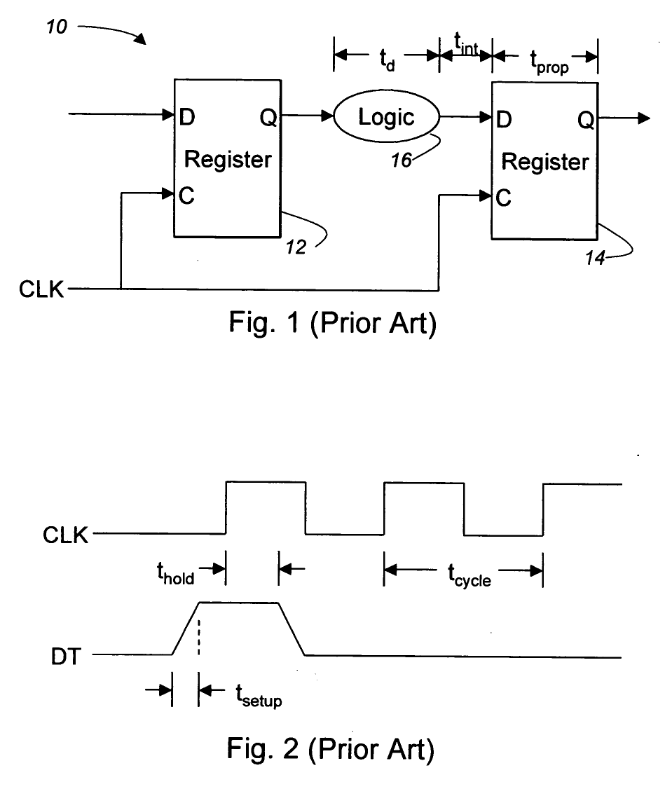

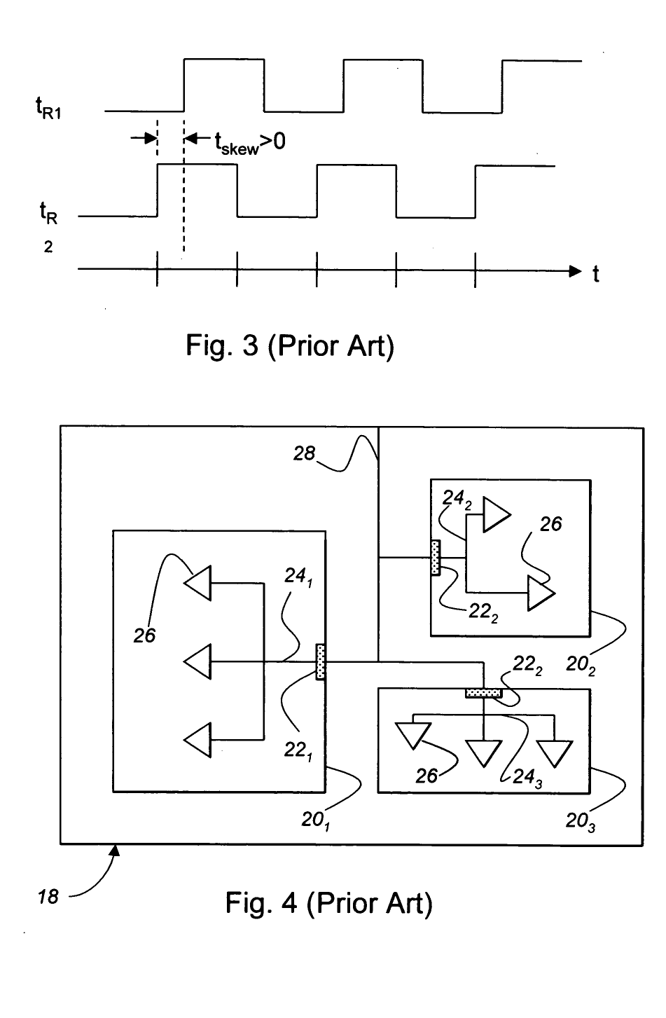

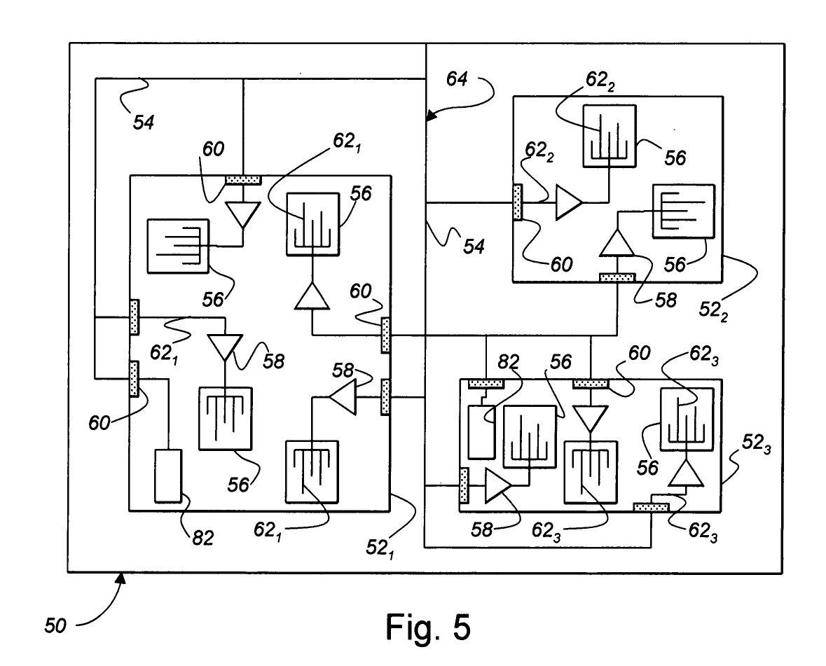

### DESCRIPTION OF THE EXEMPLARY PREFERRED EMBODIMENTS

Referring now to FIG. 5, there is shown an exemplary block based design of an integrated circuit 50 constructed according to the principles of the present invention. The circuit 50 includes a plurality of hierarchal blocks, such as blocks 52₁₋₃, and a top level clock tree 54. Each of the blocks includes a plurality of clusters 56 of sequential registers (not shown), a plurality of clock cluster buffers 58 and a plurality of clock pins 60.

As described hereinabove with respect to the first register 12 and the second register 14, each of the registers in the clusters 56 has a clock gate input. A block level clock tree 62₁₋₃ within each one of the blocks 52₁₋₃ provides a connection between each one of the clock cluster buffers 58 and the clock gate input of the sequential registers in each respective one of the clusters 56. Similarly, the block level clock tree 62₁₋₃ further provides a connection between each one of the clock pins 60 and respective one of the clock cluster buffers 58 within each one of the blocks 52₁₋₃. The top-level clock tree 54 provides a top-level clock connection to each one of the clock pins of the blocks 52₁₋₃. Together, the top level clock tree 54 and each block clock tree 621-3 provides a clock net 64 for the integrated circuit 50.

When, in accordance with one particular embodiment of the present invention, each of the clusters 56 has a substantially similar phase delay to each other, a uniform phase delay distribution at the clock pins 60 at the top level of the integrated circuits 50 occurs. Accordingly, skew balancing at the top level is facilitated and also more efficient than as known in the prior art.

For example, in Table II below, a size, given as an exemplary number of instances, for each of the blocks 52₁₋₃ is shown. Such instances may be grouped into the clusters 56 with an exemplary number of such clusters in each of the blocks 52₁₋₃ also being shown. As described above, the number of clock pins 60 shown for each of the blocks 52₁₋₃ is identical to the number of clusters in each of the blocks 52₁₋₃. The clusters 56 are formed such that each cluster 56 has a substantially similar phase delay, exemplary shown as 0.5 ns in Table II, to each other.

TABLE II

| | | | | Phase |
|---|---|---|---|---|
| Block | # Instances | # Clusters | # Pins | Delay/Cluster |
| 52₁ | 100,000 | 100 | 100 | 0.5 ns |
| 52₂ | 30,000 | 30 | 30 | 0.5 ns |
| 52₃ | 20,000 | 20 | 20 | 0.5 ns |

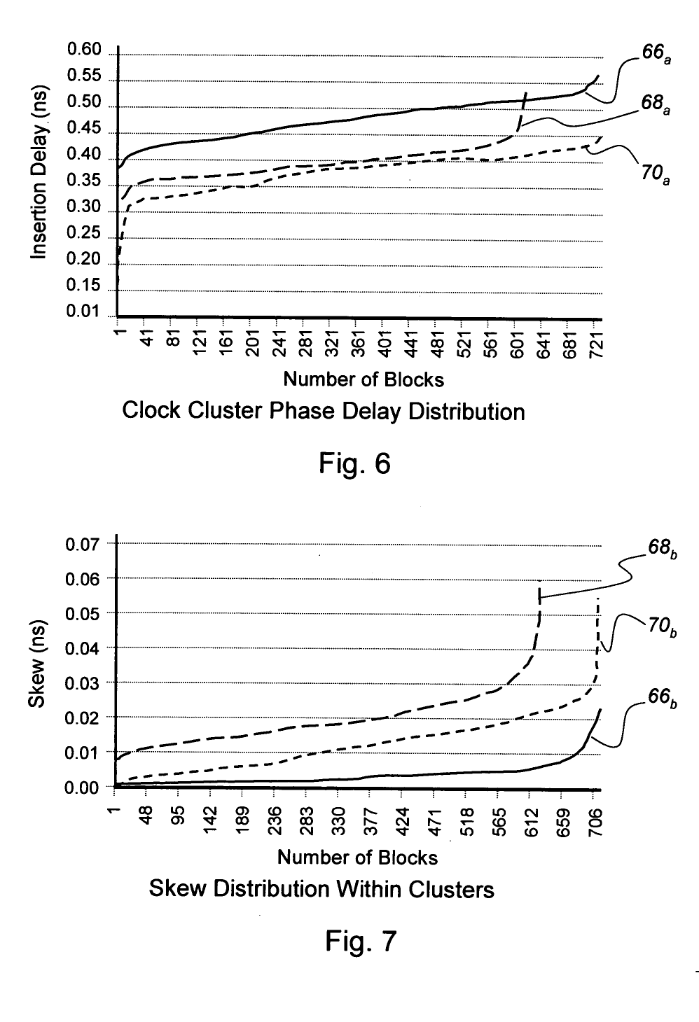

One particular advantage of the present invention can readily be seen with reference to FIG. 6, in which a clock cluster phase delay distribution is shown for insertion delay plotted against the number of blocks for three different exemplary designs. The first plot 66a and a second plot 68a were each obtained from designs having 1.5 million instances and a third plot 70a was obtained from a design having 700,000 instances. As best seen in FIG. 6, the phase delay in each one of the clusters 56 is approximately uniform irrespective of the size of the design.

Similarly, in FIG. 7, a clock cluster skew distribution is shown for skew within each of the clusters plotted against the number of blocks for the three designs described above in reference to FIG. 6. In FIG. 7, the first plot 66_{b}, the second plot 68_{b} and the third plot 70_{b} respectively correspond to the designs from which the first plot 66ₐ, the second plot 68ₐ and the third plot 70ₐ had been obtained. As best seen in FIG. 7, the skew in each of the clusters 56 is substantially uniform.

In one embodiment of the present invention, a number of each of the clusters 56 in each of the blocks 52₁₋₃ is selected as a function of a total capacitance for each of the blocks 52₁₋₃ and a maximum cluster load, each as herein below defined for one particular embodiment of the present invention. For example, the number of clusters 56 in each of the blocks 52₁₋₃ is equal to this total capacitance divided by the maximum cluster load.

The total capacitance for each of the blocks may, in one embodiment of the present invention, be a function of total clock input gate capacitance and total wire capacitance in each of the blocks 52₁₋₃. More specifically, this function may be a sum of the total capacitance for each of the blocks 52₁₋₃ and the total wire capacitance.

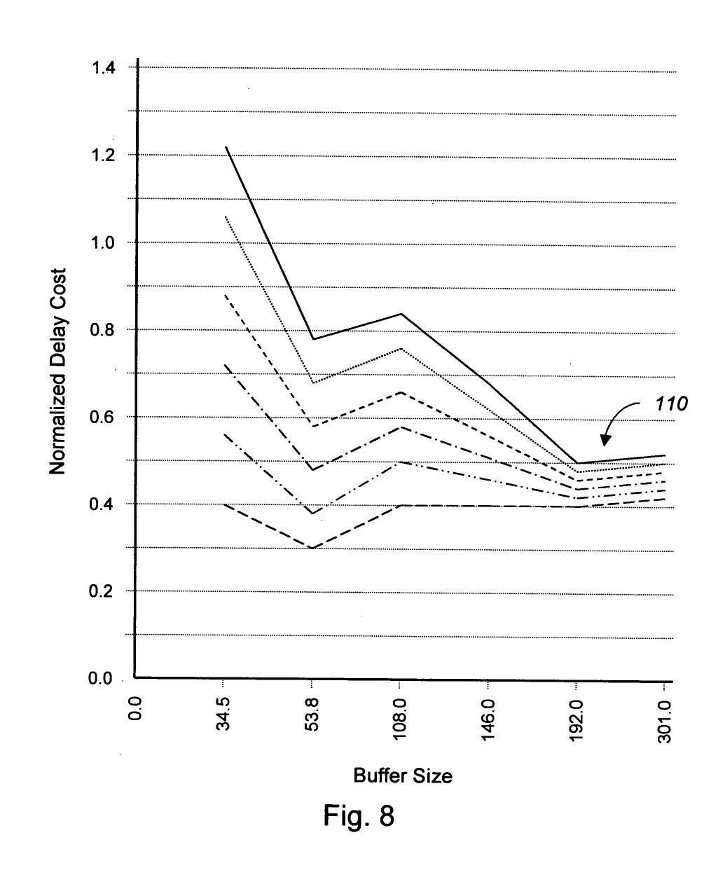

The maximum cluster load may be determined as the largest load which a selected one of the clock cluster buffers 58 can drive with minimum delay. For example, selected one of the clock buffers 58 may have the smallest normalized delay of all of the clock cluster buffers 58. As described in further detail hereinbelow, the smallest normalized delay is determined from a normalized delay cost versus buffer size, as best seen in FIG. 8 at a buffer area of 192. Furthermore, the selected one of the clock cluster buffers 58 is chosen such that when driving the maximum cluster load the maximum clock slew constraint is equal to both of the output slew and the input slew.

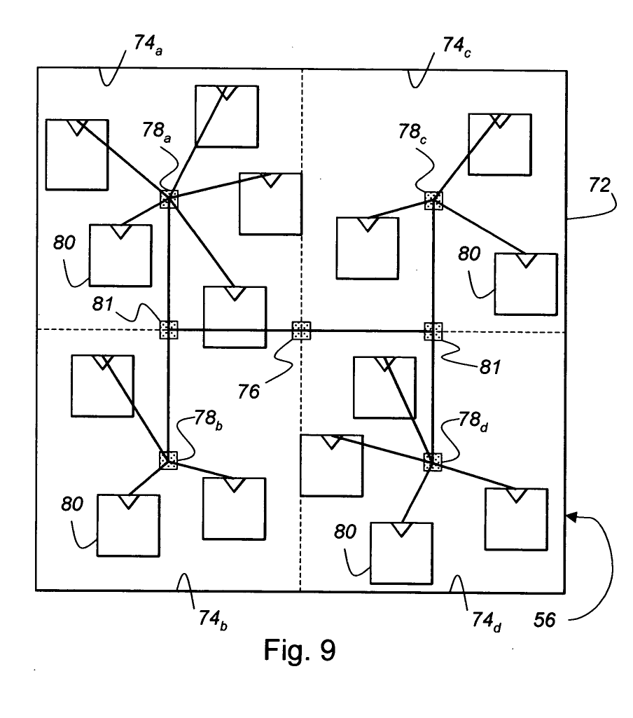

With further reference to FIG. 9, each of the clusters 56 may define a bounding box 72 having four quadrants 74a-d. The bounding box 72 may further have a centroid pin 76 and a plurality of quadrant pins 78_{a-d}. Each of the quadrant pins 78_{a-d} may then be centrally located in a respective one of the quadrants 74a-d.

The clock gate input of each of the registers 80 in one of the quadrants 74a-d is then connected to one of the quadrant pins 78a-d in the respective one of the quadrants 74a-d. Preferably, the registers in each of the clusters 56 are disposed closest to the centroid pin 76 for such cluster 56. Each of the quadrant pins 78a-d is then connectable to the centroid pin 76, with the centroid pin 76 for each of the clusters 56 being connected to a respective one of the clock cluster buffers 58 (FIG. 5).

Furthermore, the bounding box may have a pair of further pins 80, wherein each of the further pins 80 is located at a midpoint contiguous between a respective two of the quadrants 74a-d. Each of the further pins 80 is then connected to the centroid pin 76, and the quadrant pins 78a-d in the respective two of the quadrants 74a-d being connected to one of the further pins 80 contiguous therewith.

Returning to FIG. 5, in another embodiment of the present invention, at least one of the blocks 52₁₋₃ includes a partial cluster 82, a partial cluster 82 being a cluster that does not meet the criteria as hereinbelow described. In such event, any one of the blocks 52₁₋₃ includes a further clock pin 60 directly connected to the partial cluster 82. As described in further detail below, a partial cluster 82 is combinable with top level cells (not shown) to form a full cluster substantially equivalent to each of the clusters 56.

Furthermore, in another embodiment of the present invention, at least two of the blocks 52₁₋₃ include a partial cluster 82. In this case, the partial cluster 82 in one of the blocks 52₁₋₃ is combinable with the partial cluster 82 in one other of the blocks 52₁₋₃ to form a full cluster substantially equivalent to each of the clusters 56. It is further contemplated that partial clusters 82 in several ones of the blocks 52₁₋₃ are combinable with the partial cluster 82 from other ones of the blocks 52₁₋₃ to form a full cluster substantially equivalent to each of the clusters 56.

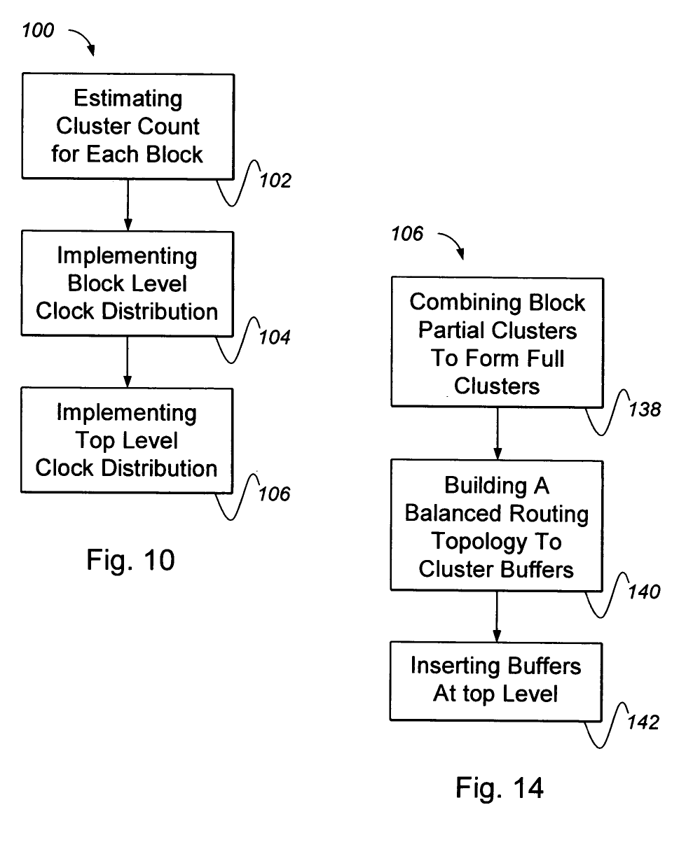

Referring now to FIG. 10, there is shown a flowchart 100 useful to describe a method of clock distribution in the integrated circuit 50 in accordance with the principles of the present invention. In its broadest aspect, the method of the present invention includes steps of estimating, as indicated at 102, in each of the hierarchal blocks 52₁₋₃ a number of the clusters 56 wherein each of the clusters 56 includes a plurality of the sequential registers 80, implementing, as indicated at 104, in each of the blocks 52₁₋₃ clock distribution to each of the clusters 56, and implementing, as indicated at 106, at a top level of the integrated circuit clock distribution to each of the hierarchal blocks.

Generally the estimating step 102 includes estimating the number of clusters in each of the hierarchal blocks 5213 as a function of a count of the sequential registers 80 in each of the blocks 52₁₋₃ and a number of the registers 80 that are capable of being driven by a selected one of the clock cluster buffers 58 within the maximum clock slew constraint. Preferably, the estimating step 102 is performed substantially contemporaneously with partitioning the integrated circuit 50 into the hierarchal blocks 52₁₋₃. Furthermore, under the estimating step 102 the size of each of the clusters 56 may be selected such that the selected one of the clock cluster buffers 58 can drive the registers 80 within the maximum clock slew requirement.

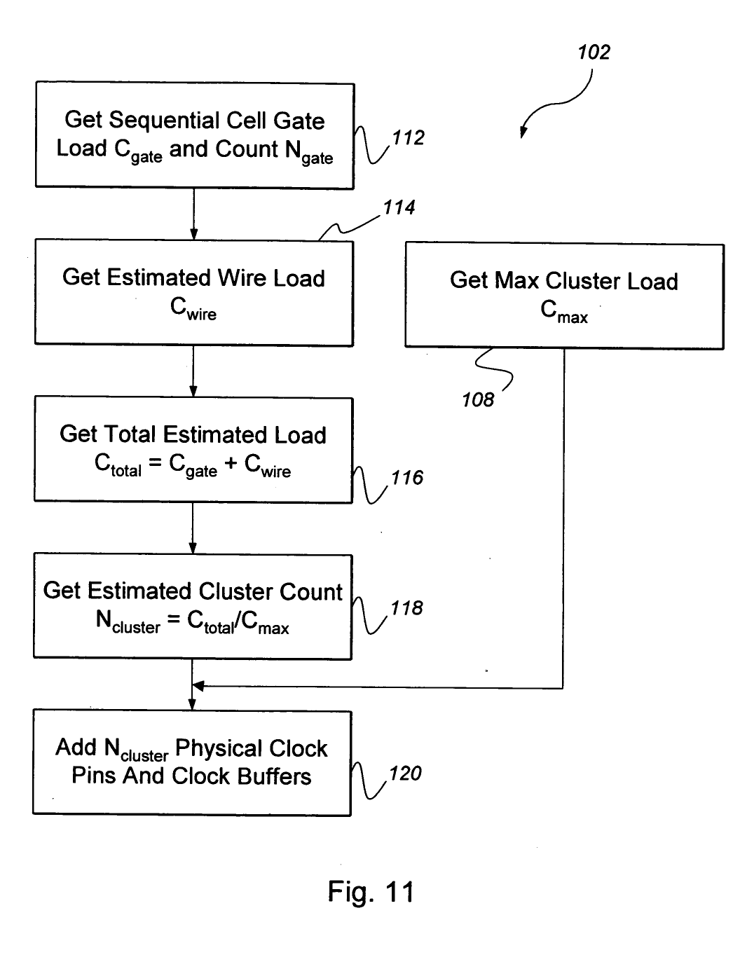

Referring now to FIG. 11, a flowchart of the estimating step 102 in one preferred embodiment of the invention is shown. As indicated at step 108, the maximum cluster capacitive load, Cₘₐₓ, resulting from the clock gate inputs of the registers 80 in each of the clusters 56 is determined such that the maximum clock slew constraint is not violated. To make this determination, a strongest one of the buffers 58 needs to be chosen.

To choose the strongest one of the buffers 58, each of the buffers 58 are pre-characterized by an accurate numerical delay calculation. A family of buffers 58 is characterized over minimum and maximum load points given in table models for the buffers 58. A family of curves, as best seen in FIG. 8, can then be plotted wherein each curve plots normalized delay of the buffers against buffer size for each load point. The buffer chosen is the one of the buffers 58 with the smallest normalized delay, as indicated at 110.

The chosen buffer will provide the maximum drive strength with minimum delay. The maximum capacitive load, Cₘₐₓ, is then the largest load the chosen buffer can drive such that the maximum clock slew constraint is equal to both of the output slew and the input slew.

At step 112, the total sequential cell clock input gate capacitance, C_{gate}, for each of the blocks 52₁₋₃ is determined. The total gate capacitance, C_{gate}, for the number, N_{gate}, of registers 80 in each one of the blocks 52₁₋₃ may be obtained by summing the clock input gate capacitances of all of the registers 80 for such block that are driven by the clock signal

At step 114, the estimated wire capacitance, C_{wire}, of the clock tree 62 in each of the blocks 52₁₋₃ is determined. In one embodiment of the present invention, it may be assumed that all of the registers 80 in each one of the blocks 52₁₋₃ are uniformly distributed with the bounding box of such block. For example the uniform distribution may be along a regular grid-like structure. The estimated wire capacitance, C_{wire}, for this grid is then computed using a shortest path algorithm. This algorithm assumes that all of the clock input gates of the registers 80 in each one of the blocks 52₁₋₃ are connect together at the center point of the block.

At step 116, the total estimated capacitive load, Cₜₒₜₐₗ, of each one of the blocks 52₁₋₃ is computed. The total capacitive load, Cₜₒₜₐₗ, may be computed as a sum of the total gate capacitance, C_{gate}, and the estimated wire capacitance, C_{write}, or

Cₜₒₜₐₗ=C_{gate}+C_{wire}.

At step 118, the estimated number, N_{cluster}, of clusters 56 in each of the blocks 52₁₋₃ may now be computed as a function of the total capacitive load and the maximum cluster load. Specifically, the estimated number of clusters 56 in each of the blocks 52₁₋₃ is equal to the total capacitive load, Cₜₒₜₐₗ, for such block divided by the maximum cluster capacitive load, Cₘₐₓ, or

N_{clusters}=Cₜₒₜₐₗ/Cₘₐₓ.

Finally, as indicated at step 120, a number of buffers 58 and clock pins 60 are provided for in each of the blocks 52₁₋₃ wherein such number of buffers 58 and clock pins 60 is equal to the number, N_{cluster}, computed for each respective one of the blocks 52₁₋₃. Returning to FIG. 10, the step 104 of implementing in each of the blocks 52₁₋₃ clock distribution to each of the clusters 56 generally includes forming the number of clusters 56 from the sequential registers 80, connecting the sequential registers 80 in each of the clusters 56 to a respective one of a plurality of clock cluster buffers 58, and connecting each of the clock cluster buffers 58 to a respective one of a plurality of clock pins 60 associated with each of the hierarchal blocks 52₁₋₃. The forming step may further include determining a maximum cluster load capacitance, Cₘₐₓ, for each of the clusters 56, grouping the sequential registers 80 into the clusters 56 such that each of the clusters 56 has a total clock net capacitance, C_{duster}, less than the maximum cluster load capacitance, Cₘₐₓ.

In performing the step 104 as hereinbelow described in greater detail, the local clock skew becomes balanced, clock phase delay is minimized and maximum clock skew constraints are realized. In the previous step, the registers 80 were grouped into the clusters 56. Described below is how the clusters 56 and the partial clusters 82 are developed. Generally, a cluster 56 has a total load capacitance comparable to the maximum cluster load capacitance, Cₘₐₓ, whereas a partial cluster 82 has a much smaller load capacitance. Whereas each full cluster 56 is driven by its own buffer 58, each partial cluster 82 is combined with top level cells or partial clusters from other blocks for a second level of clustering. In any event, each cluster and partial cluster 82 in any one of the blocks has its own clock pin 60.

Furthermore, the size of each of the clusters 56 is bounded by the maximum cluster load capacitance, Cₘₐₓ, which is further chosen, as hereinabove described, such that clock slew is not violated. Bounding the maximum cluster size and using the four quadrant routing topology as discussed above in conjunction with FIG. 9, local skew within the clusters 56 is minimized.

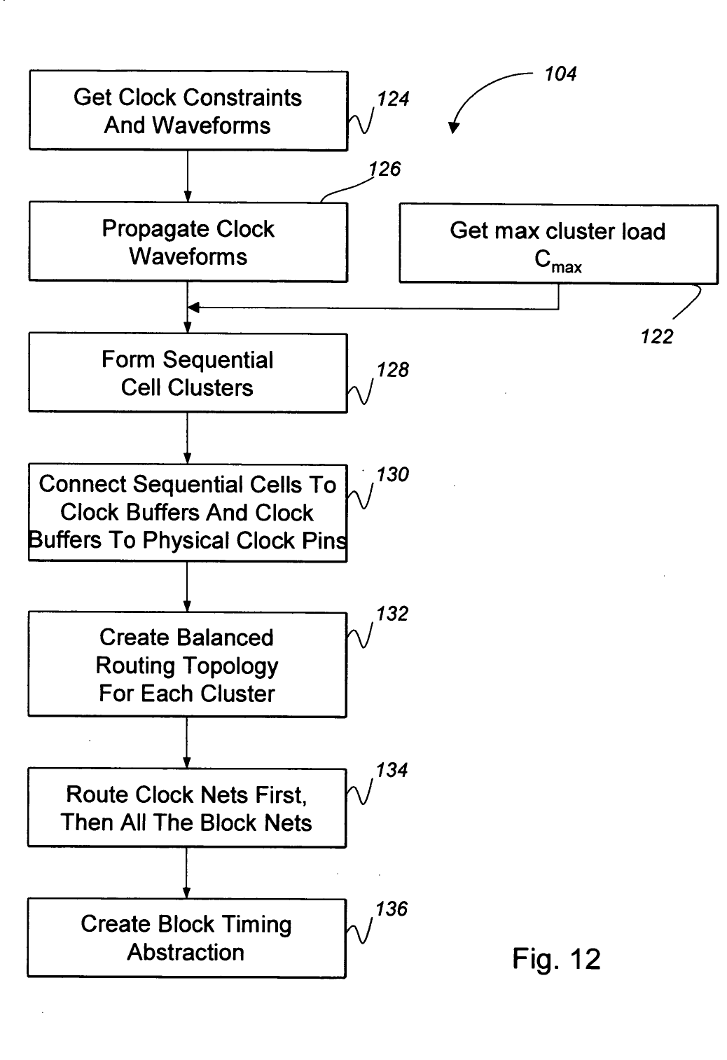

Referring now to FIG. 12, a flow chart of the implementing step 104 in one preferred embodiment of the present invention is shown. As indicated at step 122, the maximum cluster load capacitance, Cₘₐₓ, is determined, as above described.

At step 124, the clock constraint waveforms are acquired. As is well known, the clock constraints represent the requirements for clock network implementation. The clock constraints typically specify a maximum and minimum clock phase delay, a maximum skew and a maximum transition time for each clock in a design. A clock waveform specifies when a clock signal transitions from a low voltage to a high-voltage, i.e., the rise time, and conversely transitions from the high-voltage to a low voltage, i.e., the fall time. The clock constraints also specify the clock period.

At step 126, the clock waveforms are propagated in the design of the integrated circuit 50. As is known, the clock signals start at clock root terminals, propagate through wires and combinational cells, and stop at sequential register clock input terminals. Accordingly, all of the sequential registers 80 in the design can be identified and assigned to a clock domain.

At step 128, the sequential registers 80 are grouped into the clusters 56. As described above, each of the clusters 56 has a total capacitance, C_{cluster}. Similarly as described above for the total block capacitance, the total cluster capacitance, C_{cluster}, is a function of the clock input gate capacitance, C_{gate}, for each the registers 80 in each of the clusters 56, and the wire capacitance, C_{wire}, within each the clusters 56. More particularly, the total cluster capacitance, C_{cluster}, is equal to the sum of the gate capacitance, C_{gate}, and the wire capacitance C_{write}, or,

C_{cluster}=C_{gate}+C_{wire}

The clusters 56 therefore have a total cluster capacitance, C_{cluster}, less than the maximum cluster load capacitance, or:

C_{cluster}<Cₘₐₓ.

The sequential registers 80 in each of the clusters 56 are further grouped such that the registers 80 lie closest to the centroid of the cluster 56. Furthermore, sequential registers with similar insertion delays are clustered together. Clustering does not depend upon function of the registers 80.

The aspect ratio of the clusters 56, i.e., the ratio of its height to width, is maintained within reasonable limits for integrated circuit design. Preferably, the aspect ration is maintained approximately to unity. Accordingly, clustering is geometric and balanced with respect to insertion delay.

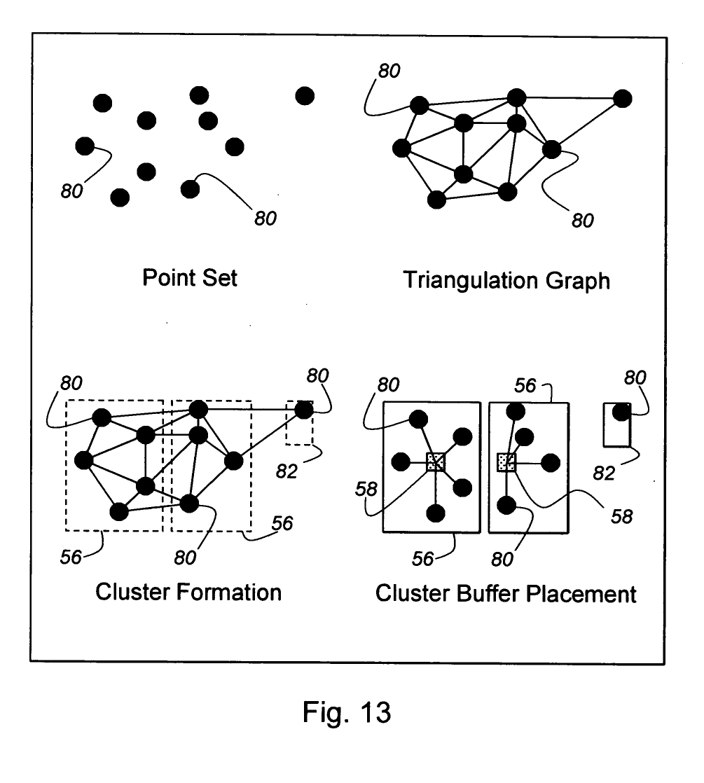

The grouping of the sequential registers 80 into the clusters 56 may also be facilitated by a Delaunay triangulation graph, as best seen in FIG. 13. The triangulation graph represents a closest point solution. Traversal of the graph edges bounded by insertion delay targets results in clusters 56 with substantially equal insertion delays. Futhermore, the traversal is bounded by Cₘₐₓ. For any of the registers 80 that do not meet the clustering criteria, these registers are grouped as the partial clusters 82, which may be combined with other partial clusters as described herein.

At step 130, the clock input gates of the sequential registers 80 in each of the clusters 56 are connected to a respective one of the clock cluster buffers 58, as shown in FIG. 5. Furthermore, also as shown in FIG. 5, each of the clock cluster buffers 58 are connected to the respective one of the clock pins 60. Preferably, the buffers 58 are placed at a centroid of the bounding box for its respective cluster 56. As can best be seen in FIG. 5, the registers 80 within a full cluster 56 have their clock input gate driven by the respective one of the clock cluster buffers 58, which in turn is connected to the respective one of the clock pins 60. However, the registers 80 in each partial cluster 82 are connected to their own clock pin 60.

At step 132, a balanced routing topology for each of the clusters 56 is developed. The balanced routing topology has been described hereinabove with respect to FIG. 9.

At step 134, routing of the clock trees 62 is performed prior to routing of the block nets in each of the blocks 52. Accordingly, the clock trees 62 are given priority during routing to avoid routing detours and ensure the balanced routing topology is maintained.

Finally, at step 136, a block timing abstraction for each of the blocks 52 is performed. The abstraction for each of the blocks 52 is used during the top level clock implementing step 106. The abstraction, as is known, is used at the top level to model timing behavior of the blocks 52 and analyze top level timing paths. Accordingly, the top level clock tree 54 is implemented after the block trees 62. The clock phase delay for block trees 62 are characterized across a range of clock slew values. Also as is known, the timing abstraction stores a timing lookup table for the maximum and the minimum phase delay for each clock pin 60. The tables are queried during the top level implementing step 106 to determine the clock phase delay for each block 52 under actual top level slew conditions.

Returning to FIG. 10, the top level clock implementing step 106 is performed after the block level implementing step 104 and assembling the blocks into the top level of the integrated circuit 50. The top level clock tree 54 is provided at the top level by combining the block level clusters 56 to balance the skew between various ones of the clusters 56. Furthermore, the top level clock tree is also designed to minimize overall phase delay of the clock signal, CLK.

Referring now to FIG. 11, there is shown a flow chart of the top level implementing step 106 of FIG. 10. As indicated at step 138, the partial clusters 82 are recombined at the top level to form full clusters substantially similar to each of the clusters 56. Since each pin 60 associated with a partial cluster 82 has stored thereat information of the capacitance that such pin 60 is driving, the registers 80 of the partial clusters 82 may be grouped at the top level in accordance with the procedures set forth above in reference to step 128 of FIG. 12, relating to the grouping of registers 80 into the clusters 56.

For example, the top level of the integrated circuit 50 includes the pins 60 for the partial clusters within blocks 52₁₋₃, and also top level cells (not shown) as is well known in the art. Partial clusters 82 and top level cells that are spatially close to each other may be combined to form top level full clusters. In any event, such top level clusters preferably meet the load criteria and driving capability of a cluster buffer 58 used to drive the full top level cluster formed from a partial cluster and top level cells. Furthermore, top level clusters may also be formed from more than one partial cluster 82 irrespective of the block 52₁₋₃ that such partial clusters 82 reside in, as long as they are spatially close to each other.

As indicated at step 140, a balanced routing topology is built to feed the global clock signal in the integrated circuit 50 to all cluster buffers 58. These cluster buffers include such buffers within the blocks 52₁₋₃ and the top level buffers 58 for top level clusters. Finally, as indicated at step 142, further buffers may be placed at the top level to match the phase delays to each cluster buffer.

There has been described hereinabove novel methods and apparatus for minimization of clocks skew and clock phase delay in integrated circuits. Those skilled in the art may now make numerous uses of, and departures from, the above described exemplary preferred embodiments without departing from the inventive principles described herein. Accordingly, the present invention is to be defined solely by the scope of the appended claims.

What is claimed as the invention is:

1. An integrated circuit comprising:
a plurality of hierarchal blocks, each of said hierarchal blocks including a plurality of registers and a plurality of clock pins, said registers in each of said blocks being grouped into a plurality of clusters, each of said clock pins being associated with a respective one of each of said clusters; and
a plurality of clock cluster buffers, each of said clock cluster buffers being interposed respective ones of said clock pins and said clusters.

2. An integrated circuit as set forth in claim 1 wherein each of said clusters has substantially uniform clock phase delay with respect to each other of said clusters.

3. An integrated circuit as set forth in claim 1 wherein a number of each of said clusters in each of said blocks is selected as a function of a total capacitance for each of said blocks and a maximum cluster load.

4. An integrated circuit as set forth in claim 3 wherein said number of clusters in each of said blocks is equal to said total capacitance divided by said maximum cluster load.

5. An integrated circuit as set forth in claim 3 wherein said total capacitance for each of said blocks is a function of total gate capacitance and total wire capacitance in each of said blocks.

6. An integrated circuit as set forth in claim 5 wherein said total capacitance for each of said blocks is a sum of said total gate capacitance and total wire capacitance in each of said blocks.

7. An integrated circuit as set forth in claim 3 wherein said maximum cluster load is determined as the largest load which a selected one of said clock cluster buffers can drive with minimum delay bounded by a maximum clock slew constraint.

8. An integrated circuit as set forth in claim 7 wherein said selected one of said clock buffers has the smallest normalized delay of all of said clock cluster buffers.

9. An integrated circuit as set forth in claim 8 wherein said smallest normalized delay is determined from a normalized delay cost versus buffer size.

10. An integrated circuit as set forth in claim 7 wherein said selected one of said buffers has an output slew substantially equal to an input slew when driving said maximum cluster load.

11. An integrated circuit as set forth in claim 1 wherein each of said clusters defines a bounding box having four quadrants, said bounding box having a centroid pin, and a plurality of quadrant pins, each of said quadrant pins being centrally located in a respective one of said quadrants, each of said registers in one of said quadrants being connected to one of said quadrant pins in said respective one of said quadrants, each of said quadrant pins being connectable to said centroid pin, said centroid pin for each of said clusters being connected to a respective one of said clock cluster buffers.

12. An integrated circuit as set forth in claim 11 wherein each of said bounding boxes has a pair of further pins, each of said further pins being located at a midpoint contiguous between a respective two of said quadrants, each of said further pins being connected to said centroid pin, said quadrant pins in said respective two of said quadrants being connected to one of said further pins contiguous therewith.

13. An integrated circuit as set forth in claim 1 wherein said registers in each of said clusters are disposed closest to said centroid pin.

14. An integrated circuit as set forth in claim 1 wherein at least one of said blocks includes a partial cluster, said block including a further clock pin directly connected to said partial cluster.

15. An integrated circuit as set forth in claim 14 wherein said partial cluster is combinable With top level cells to form a full cluster substantially equivalent to each of said clusters.

16. An integrated circuit as set forth in claim 1 in which at least two of said blocks includes a partial cluster, said partial cluster in one of said blocks being combinable with said partial cluster in one other of said blocks to form a fill cluster substantially equivalent to each of said clusters.

17. An integrated circuit as set forth in claim 16 wherein said partial cluster in a plurality of said blocks is combinable with said partial cluster from other ones of said blocks to form a full cluster substantially equivalent to each of said clusters.

18. A method of clock distribution in an integrated circuit, wherein said integrated circuit includes a plurality of hierarchal blocks and further wherein each of said hierarchal blocks has a plurality of sequential registers, said method comprising steps of:
estimating in each of said hierarchal blocks a number of clusters wherein each of said clusters includes a plurality of said sequential registers;
implementing in each of said blocks clock distribution to each of said clusters; and
implementing at a top level of said integrated circuit clock distribution to each of said hierarchal blocks.

19. A method as set forth in claim 18 wherein said estimating step includes the step of further estimating said number of clusters in each of said hierarchal blocks as a function of a count of said sequential registers in each of said blocks and a number of said registers that are capable of being driven by a selected one of a plurality of clock cluster buffers such that a capacitive load of each of said clusters is similar to each other.

20. A method as set forth in claim 19 wherein said further estimating step is performed substantially contemporaneously with partitioning said integrated circuit into said hierarchal blocks.

21. A method as set forth in claim 19 wherein said further estimating step includes the step of selecting a size of each of said clusters such that said selected one of said clock cluster buffers can drive said registers within a maximum clock slew.

22. A method as set forth in claim 18 wherein said estimating step includes the step of computing said number of said clusters in each of said hierarchal blocks as a function of an estimated total clock net capacitance in each of said blocks and a maximum cluster load capacitance.

23. A method as set forth in claim 22 wherein said computing step includes the step of selecting from a plurality of clock cluster buffers one of said buffers having a smallest normalized delay, said maximum cluster load capacitance being the largest capacitive load said selected one of said clock cluster buffers can drive within a maximum clock slew constraint.

24. A method as set forth in claim 23 wherein said selecting step further includes the step of setting said maximum clock slew constraint substantially equal to each of an input slew and an output slew.

25. A method as set forth in claim 23 wherein said selecting step further includes step of:
pre-characterizing said clock cluster buffers by a numerical delay calculation in which said clock cluster buffers are characterized between minimum and maximum load points; and
plotting for each of said load points a family of curves wherein a normalized delay is plotted as a function of buffer size, said selected one of said buffers being selected from said family of curves.

26. A method as set forth in claim 22 wherein said computing step includes the step of estimating said total clock net capacitance in each of said hierarchal blocks as a function of a total sequential cell clock input gate capacitance and an estimated wire capacitance.

27. A method as set forth in claim 26 wherein said total clock net capacitance estimating step includes the step of summing said total sequential cell clock input gate capacitance and said estimated wire capacitance.

28. A method as set forth in claim 26 wherein said total clock net capacitance estimating step includes the step of calculating said total sequential cell clock input gate capacitance as a sum of a clock input gate capacitance of each of said registers.

29. A method as set forth in claim 26 wherein said total clock net capacitance estimating step includes the steps of:
modeling each of said hierarchal blocks as a distributed grid of said registers; and
summing a wire capacitance from a centroid of said grid to each of said registers to derive said estimated wire capacitance.

30. A method as set forth in claim 22 wherein said computing step includes the step of dividing said estimated total clock net capacitance by said maximum cluster load capacitance to derive said number of said clusters.

31. A method as set forth in claim 18 further comprising the step of providing in each of said hierarchal blocks a plurality of clock cluster buffers and a plurality of clock pins, wherein each of said clock cluster buffers and said clock pins are associated with a respective one of said clusters.

32. A method as set forth in claim 18 wherein said clock distribution in each of said hierarchal blocks implementing step includes the steps of:
forming said number of clusters from said sequential registers;
connecting said sequential registers in each of said clusters to a respective one of a plurality of clock cluster buffers; and
connecting each of said clock cluster buffers to a respective one of a plurality of clock pins associated with each of said hierarchal blocks.

33. A method as set forth in claim 32 wherein said forming step includes steps of:
determining a maximum cluster load capacitance for each of said clusters; and
grouping said sequential registers into said clusters such that each of said clusters has a total clock net capacitance less than said maximum cluster load capacitance.

34. A method as set forth in claim 33 wherein said grouping step includes the step of computing said total clock net capacitance in each of said clusters as a function of a total sequential cell clock input gate capacitance and an estimated wire capacitance.

35. A method as set forth in claim 34 wherein said computing step includes the step of summing said total sequential cell clock input gate capacitance and said estimated wire capacitance in each of said clusters to derive said total clock net capacitance in each of said clusters.

36. A method as set forth in claim 35 wherein said summing step includes the step of adding a capacitance of a clock input of each of said registers in each of said clusters to derive said total sequential cell clock input gate capacitance for each of said clusters.

37. A method as set forth in claim 35 wherein said computing step includes the step of summing a wire capacitance from said centroid of each of said clusters to each of said registers to derive said estimated wire capacitance in each of said clusters.

38. A method as set forth in claim 37 wherein said placing step includes the step of grouping said registers in each of said clusters such that groups of said registers have a similar insertion delay to each other.

39. A method as set forth in claim 37 wherein said placing step includes the step of maintaining an aspect ratio of each of said clusters approximately equal to unity.

40. A method as set forth in claim 33 further comprising steps of:
forming at least one partial cluster in one of said hierarchal blocks from any of said registers remaining in said one of said hierarchal blocks after performing said grouping step; and
connecting said sequential registers in said partial cluster to a clck pin of said one of said hierarchal blocks associated with said partial cluster.

41. A method as set forth in claim 32 wherein said forming step includes the steps of:
propagating a clock waveform in each of said hierarchal blocks from a clock root terminal to a clock input terminal of each of said registers; and
identifying from said propagating step which of said registers belong to a clock domain to assign registers to a clock domain such that said registers assigned to said clock domain are grouped in one of said clusters.

42. A method as set forth in claim 40 wherein said forming step further includes the step of acquiring clock constraints for said clock waveform.

42. A method as set forth in claim 32 further comprising the step of balancing a routing topology of a clock net in each of said clusters.

43. A method as set forth in claim 42 wherein said balancing step includes the steps of:
defining for each of said clusters a quadrant topology;
providing a first pin at a centroid of said quadrant topology of each of said clusters for connection to a respective one of said clock cluster buffers;
providing a second pin at a centroid of each quadrant for connection to a clock input terminal of each of said registers in each respective quadrant; and
connecting said first pin to each second pin.

44. A method as set forth in claim 43 wherein said first pin connecting step includes the steps of:
providing a pair of third pins wherein each of said third pins is disposed at a boundary between a respective pair of said quadrants and spaced substantially equidistantly form said first pin; and
connecting said third pins to said first pin and further connecting each of said third pins to each second pin in said respective pair of said quadrants.

45. A method as set forth in claim 32 further comprising the step of routing clock nets in each of said hierarchal blocks prior to routing block nets.

46. A method as set forth in claim 32 developing a timing abstraction for each of said hierarchal blocks for use during said top level clock distribution implementing step.

47. A method as set forth in claim 18 wherein said top level clock distribution implementing step includes steps of
balancing a routing topology of a top level clock net to each of said clock cluster buffers; and
providing clock buffers at said top level to match phase delays to said clock cluster buffers.

48. A method as set forth in claim 47 further comprising the step of combining partial clusters of said sequential registers in any of said hierarchal blocks to form at least one top level cluster.

49. A hierarchal block for an integrated circuit comprising:
a plurality of sequential registers, each of said sequential registers having a clock gate input, said sequential registers being grouped into a plurality of clusters;
a plurality of clock cluster buffers, each of said clock cluster buffers being associated with a respective one of said clusters; and
a plurality of clock pins, each of said clock pins being associated with a respective one of said clock cluster buffers.

50. A hierarchal block as set forth in claim 49 wherein each of said clusters has substantially uniform clock phase delay with respect to each other of said clusters.

51. A hierarchal block as set forth in claim 49 wherein a number of each of said clusters in said logic block is selected as a function of a total capacitance of said block and a maximum cluster load.

52. A hierarchal block as set forth in claim 51 wherein said number of clusters in said block is equal to said total capacitance divided by said maximum cluster load.

53. A hierarchal block as set forth in claim 51 wherein said total capacitance for said block is a function of total sequential register clock input gate capacitance and total wire capacitance in said block.

54. A hierarchal block as set forth in claim 53 wherein said total capacitance for said block is a sum of said total sequential register clock input gate capacitance and total wire capacitance in said block.

55. A hierarchal block as set forth in claim 51 wherein said maximum cluster load is determined as the largest load which a selected one of said clock cluster buffers can drive within a maximum clock slew constraint.

56. A hierarchal block as set forth in claim 55 wherein said selected one of said clock buffers has the smallest normalized delay of all of said clock cluster buffers.

57. A hierarchal block as set forth in claim 56 wherein said smallest normalized delay is determined from a normalized delay cost versus buffer size.

58. A hierarchal block as set forth in claim 55 wherein said selected one of said buffers has an output slew substantially equal to an input slew when driving said maximum cluster load.

59. An hierarchal block as set forth in claim 49 wherein each of said clusters defines a bounding box having four quadrants, said bounding box having a centroid pin, and a plurality of quadrant pins, each of said quadrant pins being centrally located in a respective one of said quadrants, each of said registers in one of said quadrants being connected to one of said quadrant pins in said respective one of said quadrants, each of said quadrant pins being connectable to said centroid pin, said centroid pin for each of said clusters being connected to a respective one of said clock cluster buffers.

60. An hierarchal block as set forth in claim 59 wherein each of said bounding boxes has a pair of further pins, each of said further pins being located at a midpoint contiguous between a respective two of said quadrants, each of said further pins being connected to said centroid pin, said quadrant pins in said respective two of said quadrants being connected to one of said further pins contiguous therewith.

61. An hierarchal block as set forth in claim 59 wherein said registers in each of said clusters are disposed closest to said centroid pin.

62. An hierarchal block as set forth in claim 49 wherein said block includes a partial cluster and a further clock pin directly connected to said partial cluster.

63. An hierarchal block as set forth in claim 62 wherein said partial cluster is combinable with top level cells to form a full cluster substantially equivalent to each of said clusters.

64. A method of clock distribution in a hierarchal block having a plurality of sequential registers comprising steps of:
forming from said sequential registers a plurality of clusters;
connecting said sequential registers in each of said clusters to a respective one of a plurality of clock cluster buffers; and
connecting each of said clock cluster buffers to a respective one of a plurality of clock pins associated with said hierarchal block.

65. A method as set forth in claim 64 wherein said forming step includes steps of:
determining a maximum cluster load capacitance for each of said clusters; and
grouping said sequential registers into said clusters such that each of said clusters has a total clock net capacitance less than said maximum cluster load capacitance.

66. A method as set forth in claim 65 wherein said grouping step includes the step of computing said total clock net capacitance in each of said clusters as a function of a total sequential cell clock input gate capacitance and an estimated wire capacitance.

67. A method as set forth in claim 66 wherein said computing step includes the step of summing said total sequential cell clock input gate capacitance and said estimated wire capacitance in each of said clusters to derive said total clock net capacitance in each of said clusters.

68. A method as set forth in claim 67 wherein said summing step includes the step of adding a capacitance of a clock input of each of said registers in each of said clusters to derive said total sequential cell clock input gate capacitance for each of said clusters.

69. A method as set forth in claim 67 wherein said computing step includes the steps of:
placing said sequential registers in each of said clusters closest to a centroid of said clusters; and
summing a wire capacitance from said centroid of each of said clusters to each of said registers to derive said estimated wire capacitance in each of said clusters.

70. A method as set forth in claim 69 wherein said placing step includes the step of grouping said registers in each of said clusters such that groups of said registers have a similar insertion delay to each other.

71. A method as set forth in claim 69 wherein said placing step includes the step of maintaining an aspect ratio of each of said clusters approximately equal to unity.

72. A method as set forth in claim 65 further comprising steps of:
forming at least one partial cluster in said hierarchal block from any of said registers remaining in said hierarchal block after performing said grouping step; and
connecting said sequential registers in said partial cluster to a further clock pin of said hierarchal block associated with said partial cluster.

73. A method as set forth in claim 64 wherein said forming step includes the steps of:
propagating a clock waveform in said hierarchal block from a clock root terminal to a clock input terminal of each of said registers; and
identifying from said propagating step which of said registers belong to a clock domain to assign registers to a clock domain such that said registers assigned to said clock domain are grouped in one of said clusters.

74. A method as set forth in claim 73 wherein said forming step further includes the step of acquiring clock constraints for said clock waveform.

75. A method as set forth in claim 64 further comprising the step of step of balancing a routing topology of a clock net in each of said clusters.

76. A method as set forth in claim 75 wherein said balancing step includes the steps of:
defining for each of said clusters a quadrant topology;
providing a first pin at a centroid of said quadrant topology of each of said clusters for connection to a respective one of said clock cluster buffers;
providing a second pin at a centroid of each quadrant for connection to a clock input terminal of each of said registers in each respective quadrant; and
connecting said first pin to each second pin.

77. A method as set forth in claim 76 wherein said first pin connecting step includes the steps of:
providing a pair of third pins wherein each of said third pins is disposed at a boundary between a respective pair of said quadrants and spaced substantially equidistantly form said first pin; and
connecting said third pins to said first pin and further connecting each of said third pins to each second pin in said respective pair of said quadrants.

78. A method as set forth in claim 64 further comprising the step of routing a clock net in said hierarchal block prior to routing a block net.
